(19) United States
(12) Patent Application Publication
(10) Pub. No.: US 2005/0261397 A1
(43) Pub. Date: Nov. 24, 2005

(54) Epoxy resin composition for optical semiconductor element encapsulation and optical semiconductor device which uses the same

(75) Inventor: Hisataka Ito, Ibaraki-shi (JP)

Correspondence Address: SUGHRUE MION, PLLC, 2100 PENNSYLVANIA AVENUE, N.W., SUITE 800, WASHINGTON, DC, 20037, US

(73) Assignee: NITTO DENKO CORPORATION

(21) Appl. No.: 11/129,495

(22) Filed: May 16, 2005

(30) Foreign Application Priority Data
May 18, 2004 (JP) P. 2004-148182

(51) Int. Cl. C08L 63/00; H01L 21/56; B32B 27/38

(52) U.S. Cl. 523/400; 428/413; 438/127

(57) ABSTRACT

An epoxy resin composition for optical semiconductor element encapsulation, which is excellent in moisture resistance due to low hygroscopicity, heat resistant light transmittance and low stress property. The epoxy resin composition for optical semiconductor element encapsulation, which comprises the following components (A) to (C):
(A) an epoxy resin composition comprising the alicyclic epoxy resin represented by the following structural formula (1) in an amount of 20% by weight or more based on the entire epoxy resin components, 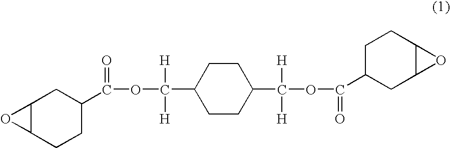 (B) a curing agent, and (C) a curing accelerator.

### FIELD OF THE INVENTION

The present invention relates to an epoxy resin composition for optical semiconductor element encapsulation, which is excellent in heat resistant light transmittance, low stress property and moisture resistance, and an optical semiconductor device encapsulated with the same.

### BACKGROUND OF THE INVENTION

As the resin composition for encapsulation which is used in encapsulating optical semiconductor elements such as light emitting diode (LED), it is required that the cured resin composition should have transparency. Accordingly, in general, epoxy resin compositions obtained by using epoxy resins such as bisphenol A epoxy resin, alicyclic epoxy resin and the like and an acid anhydride as the curing agent are used widely for various purposes.

In addition, from the viewpoint of heat resistance and reduction of ionic impurities contained, an epoxy resin composition which uses an alicyclic epoxy resin represented by the following structural formula (2) has been proposed (cf. Reference 1) 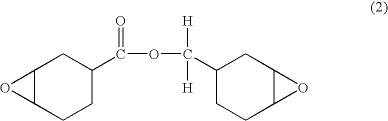
Reference 1: JP-A-7-309927

### SUMMARY OF THE INVENTION

However, the optical semiconductor device encapsulated with an epoxy resin composition which uses the alicyclic epoxy resin represented by the aforementioned structural formula (2), mechanical brittleness and hygroscopic property of the cured resin product of this alicyclic epoxy resin are increased due to its high glass transition temperature (Tg). As a result, when an optical semiconductor element is encapsulated with this epoxy resin composition, reduction of cracking of the resin against mechanical stress and its hygroscopicity reliability are not sufficiently satisfactory. Accordingly, there is a demand for an epoxy resin composition which can be used as a low stress and low hygroscopic encapsulation material.

The present invention has been made by taking such circumstances into consideration, and an object of the present invention is to provide an epoxy resin composition for optical semiconductor element encapsulation, which is excellent in moisture resistance due to low hygroscopicity, heat resistant light transmittance and low stress property, and an optical semiconductor device which uses the same.

In order to achieve the aforementioned object, the first embodiment of the present invention is an epoxy resin composition for optical semiconductor element encapsulation, which comprises the following components (A) to (C):
(A) an epoxy resin composition comprising the alicyclic epoxy resin represented by the following structural formula (1) in an amount of 20% by weight or more based on the entire epoxy resin components, 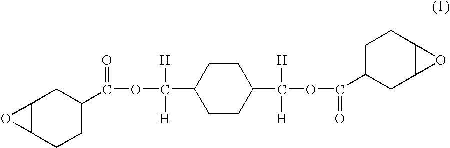
(B) a curing agent, and
(C) a curing accelerator.

The second embodiment of the present invention is an optical semiconductor device which comprises an optical semiconductor element and the above-described epoxy resin composition for optical semiconductor element encapsulation which encapsulates the optical semiconductor element.

That is, with the aim of overcoming the brittleness and high hygroscopic property as disadvantages possessed by an alicyclic epoxy resin represented by the aforementioned structural formula (2) which has superior heat resistant light transmittance effected by the possession of high heat resistance, the present inventors have conducted extensive studies mainly on epoxy resins. As a result, it was unexpectedly found that improvement of not only the heat resistant light transmittance but also moisture resistance and cracking resistance effected by the lowering of stress can be achieved when the alicyclic epoxy resin having a specific structure represented by the structural formula (1) (component (A)) is used as the epoxy resin at a specified ratio, thus resulting in the present invention.

As described in the above, the present invention is an epoxy resin composition for optical semiconductor element encapsulation, which uses epoxy resins containing the aforementioned alicyclic epoxy resin represented by the structural formula (1) (component (A)) at a specified ratio. Reduction of internal stress can be effected, lowering of stress can be realized and excellent moisture resistance can be obtained, so that deterioration of optical semiconductor elements can be effectively prevented. What is more, superior heat resistant light transmittance can be obtained. Accordingly, the optical semiconductor device prepared by encapsulating an optical semiconductor element with the epoxy resin composition for optical semiconductor element encapsulation of the present invention is excellent in reliability, so that its function can be sufficiently exerted.

### DETAILED DESCRIPTION OF THE INVENTION

The epoxy resin composition for optical semiconductor element encapsulation of the present invention is obtained by using epoxy resins containing a specified epoxy resin (component A), a curing agent (component B) and a curing accelerator (component C).

The aforementioned specified epoxy resin in the aforementioned epoxy resins containing a specified epoxy resin (component A) is an alicyclic epoxy resin represented by the following structural formula (1) which is a special epoxy resin in which a cyclohexyl ring structure is introduced into the principal chain part. By the possession of such a structure, reduction of glass transition temperature (Tg) becomes possible and improvement of low stress property can be attained.

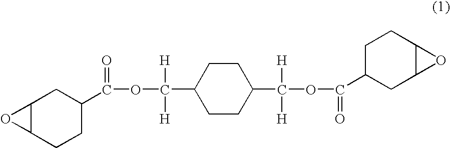

Thus, according to the present invention, the use of epoxy resins containing the aforementioned alicyclic epoxy resin represented by the structural formula (1) (component A) at a specified ratio is the greatest characteristic, and in the aforementioned whole epoxy resins (component A), other epoxy resin is used jointly with the aforementioned alicyclic epoxy resin represented by the structural formula (1).

The aforementioned other epoxy resin is not particularly limited, and its examples include various conventionally known epoxy resins such as bisphenol A type epoxy resin, bisphenol F type epoxy resin, phenol novolak type epoxy resin, cresol novolak type epoxy resin and the like novolak type epoxy resins, alicyclic epoxy resin, triglycidyl isocyanurate, hydantoin epoxy resin and the like nitrogen-containing cyclic epoxy resins, hydrogenated bisphenol A type epoxy resin, aliphatic epoxy resin, glycidyl ether type epoxy resin, bisphenol S type epoxy resin, biphenyl type epoxy resin as the main stream of low water absorption hardening type, dicyclo ring type epoxy resin, naphthalene type epoxy resin and the like. These can be used alone or as a mixture of two or more. Among these epoxy resins, from the viewpoint of excellent transparency and discoloration resistance, it is desirable to use bisphenol A type epoxy resin, bisphenol F type epoxy resin, novolak type epoxy resin, alicyclic epoxy resin or triglycidyl isocyanurate. More illustratively, from heat resistant light transmittance, low ionic impurities and the like points of view, it is particularly desirable to jointly use an alicyclic epoxy resin represented by the following structural formula (2) in an amount of 50% by weight or more based on the whole other epoxy resins.

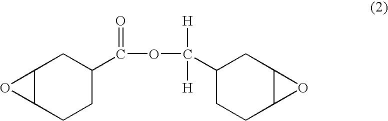

According to the present invention, the aforementioned other epoxy resin is used in combination with the aforementioned alicyclic epoxy resin represented by the structural formula (1), and it is necessary from the low stress property point of view to use the aforementioned alicyclic epoxy resin represented by the structural formula (1) in an amount of at least 20% by weight, more preferably 30% by weight or more, particularly preferably 50% by weight or more, based on the whole epoxy resin components. This is because its effect to improve moisture resistance and low stress property may not be obtained when the aforementioned alicyclic epoxy resin represented by the structural formula (1) is less than 20% by weight of the whole epoxy resin components.

In addition, as such epoxy resin components, they may be either solid or liquid, but it is generally desirable that average epoxy equivalent of the epoxy resin to be used is from 90 to 1,000, and those which have a softening point of 160° C. or less are desirable when they are solid. That is, this is because a hardened product of the epoxy resin composition for optical semiconductor element encapsulation may become brittle in some cases when the epoxy equivalent is smaller than 90. When the epoxy equivalent exceeds 1,000, glass transition temperature (Tg) of the hardened product may become low in some cases. In this connection, the aforementioned ordinary temperature according to the present invention is within the range of from 5 to 35° C.

As the aforementioned curing agent (component B), an acid anhydride system curing agent or a phenol system curing agent can for example be cited. Examples of the aforementioned acid anhydride system curing agent include phthalic anhydride, maleic anhydride, trimellitic anhydride, pyromellitic anhydride, hexahydrophthalic anhydride, tetrahydrophthalic anhydride, methyl nadic anhydride, nadic anhydride, glutaric anhydride, methyl hexahydrophthalic anhydride, methyl tetrahydrophthalic anhydride and the like. These can be used alone or as a mixture of two or more. Among these acid anhydride system curing agents, it is desirable to use phthalic anhydride, hexahydrophthalic anhydride, tetrahydrophthalic anhydride or methyl hexahydrophthalic anhydride. Regarding the aforementioned acid anhydride system curing agents, those which have a molecular weight of approximately from 140 to 200 are desirable, and colorless to pale yellow acid anhydrides are desirable.

Examples of the aforementioned phenol system curing agent include phenol novolak resin-based curing agent.

It is preferable to set the mixing ratio of the aforementioned specific epoxy resin (component A) and curing agent (component B) to such a ratio that the active group which can react with epoxy group (acid anhydride group or hydroxyl group) in the curing agent (component B) becomes from 0.5 to 1.5 equivalents, preferably from 0.7 to 1.2 equivalents, based on 1 epoxy group equivalent in the aforementioned specific epoxy resin (component A). This is because the hardening rate of the epoxy resin composition for optical semiconductor element encapsulation may be delayed and glass transition temperature of its hardened product tends to decrease when the active group is less than 0.5 equivalent, and there is a tendency of reducing moisture resistance when it exceeds 1.5 equivalents.

In addition, regarding the aforementioned curing agent (component B), depending on its object and use, in addition to the aforementioned acid anhydride system curing agent and phenol system curing agent, a conventionally known epoxy resin curing agent, such as an amine system curing agent, a product of the aforementioned acid anhydride system curing agent partially esterified with an alcohol, or a curing agent of hexahydrophthalic acid, tetrahydrophthalic acid, methyl hexahydrophthalic acid or the like polyvalent carboxylic acid, may be used alone or jointly with an acid anhydride system curing agent and a phenol system curing agent. For example, when a curing agent of a polyvalent carboxylic acid is jointly used, it quickly reacts with the epoxy resin, so that a resin composition of a B-stage form (semi-cured form) having the necessary viscosity can be obtained without causing gelation, and productivity of the composition can therefore be improved. In this connection, also in the case of the use of these curing agents, their blending ratio may be decided in accordance with the blending ratio (equivalent ratio) in the case of the use of an acid anhydride system curing agent and a phenol system curing agent.

The curing accelerator (component C) to be used together with the aforementioned component A and component B is not particularly limited, and its examples include 1,8-diaza-bicyclo(5,4,0)undecene-7, triethylenediamine, tri-2,4,6-dimethylaminomethylphenol and the like tertiary amines, 2-ethyl-4-methylimidazole, 2-methylimidazole and the like imidazoles, triphenylphosphine, tetraphenylphosphonium tetraphenylborate, tetra-n-butylphosphonium-o,o-diethylphosphoro dithioate and the like phosphorus compounds, quaternary ammonium salts, organic metal salts and derivatives thereof. These can be used alone or as a mixture of two or more. Among these curing accelerators, it is desirable to use tertiary amines, imidazoles and phosphorus compounds.

It is desirable that the mixing amount of the aforementioned curing accelerator (component C) is set to a range of preferably from 0.01 to 8 parts by weight (to be referred to as “part(s)” or “weight part(s)” hereinafter), more preferably from 0.1 to 3.0 parts based on 100 parts of the aforementioned specified epoxy resin (component A). This is because sufficient hardening accelerating effect may not be obtained when it is less than 0.01 part, and discoloration may be found sometimes on the obtained hardened product when it exceeds 8 parts.

Also, in addition to the aforementioned epoxy resins containing the specified epoxy resin (component A), curing agent (component B) and curing accelerator (component C), conventionally used deterioration preventing agent, a modifying agent, a silane coupling agent, a defoaming agent, a leveling agent, a mold releasing anent, a dyestuff, a pigment and the like various additives may be optionally blended with the epoxy resin composition for optical semiconductor element encapsulation of the present invention as occasion demands.

As the aforementioned deterioration preventing agent, for example, a phenol system compound, an amine system compound, an organic sulfur system compound, a phosphine system compound and the like conventionally known deterioration preventing agents can be cited. As the aforementioned modifying agent, for example, glycols, silicones, alcohols and the like conventionally known modifying agent can be cited. As the aforementioned silane coupling agent, for example, silane system, titanate system and the like conventionally known silane coupling agents can be cited. As the aforementioned defoaming agent, for example, silicone system and the like conventionally known defoaming agents can be cited.

In addition, the epoxy resin composition for optical semiconductor element encapsulation of the present invention can be obtained in the form of a liquid, a powder or a tablet made from the powder, by producing it in the following manner. That is, in order to obtain a liquid epoxy resin composition for optical semiconductor element encapsulation, for example, the aforementioned respective components, namely the aforementioned components A to C, and various additives which are blended as occasion demands, may be optionally formulated. In addition, when it is obtained in the form of a powder or a tablet made from the powder, for example, the aforementioned respective components are optionally formulated to carry out preliminary mixing, and the mixture is kneaded using a kneader to carry out melt mixing, and then this is cooled down to room temperature and pulverized by a conventionally known means, if necessary further carrying out tablet making.

The epoxy resin composition for optical semiconductor element encapsulation of the present invention obtained in this manner is used for the encapsulation of optical semiconductor elements such as LED, charge coupled device (CCD) and the like. That is, encapsulation of an optical semiconductor element using the epoxy resin composition for optical semiconductor element encapsulation of the present invention is not particularly limited and can be carried out by a general transfer molding, cast molding or the like conventionally known molding method. In this connection, when the epoxy resin composition for optical semiconductor element encapsulation of the present invention is in a liquid state, it may be used as a so-called two-component type in which at least the epoxy resin components and curing agent are separately stored and then mixed just before use. In addition, when the epoxy resin composition for optical semiconductor element encapsulation of the present invention is in the form of a powder or tablet, it may be made into a B-stage (semi-hardened state) at the time of melt-mixing the aforementioned respective components, and this is heat-melted when used.

By encapsulating an optical semiconductor element with the epoxy resin composition for optical semiconductor element encapsulation of the present invention, reduction of internal stress can be effected, and deterioration of the optical semiconductor element can be effectively prevented by the improvement of moisture resistance. In addition, superior heat resistant light transmittance can be obtained. Accordingly, the optical semiconductor device of the present invention in which an optical semiconductor element is sealed with the epoxy resin composition for optical semiconductor element encapsulation of the present invention is excellent in reliability and low stress property so that its function can be sufficiently exerted.

Next, Examples are described together with Comparative Examples.

Respective components shown below were prepared prior to the examples.

Epoxy Resin a:

An alicyclic epoxy resin represented by the aforementioned structural formula (1) (epoxy equivalent 205-210)
   Epoxy Resin b:
An alicyclic epoxy resin represented by the aforementioned structural formula (2) (epoxy equivalent 134)
   Epoxy Resin c:
A bisphenol A type epoxy resin (epoxy equivalent 185)
   Acid Anhydride System Curing Agent:
A mixture of 4-methyl hexahydrophthalic anhydride (x) and hexahydrophthalic anhydride (y) (mixing weight ratio x:y=7:3) (acid anhydride equivalent 168)
   Curing Accelerator:
Tetra-n-butylphosphonium-o,o-diethylphosphorodithioate
   Deterioration Preventing Agent:
9,10-Dihydro-9-oxa-10-phosphaphenanthrene-10-oxide
   Antifoaming Agent:
Silicone oil
   Modifying Agent:
Propylene glycol

### EXAMPLES 1 TO 4, COMPARATIVE EXAMPLES 1 TO 3

Respective components shown in the following Table 1 were blended at the ratio shown in the same table, melt-mixed at 80 to 110° C., solidified by cooling, and then pulverized and made into tablets, thereby preparing respective epoxy resin compositions of interest.

TABLE 1

| | | Examples | | | | Comparative Examples | | |
|---|---|---|---|---|---|---|---|---|
| | | 1 | 2 | 3 | 4 | 1 | 2 | 3 |
| Epoxy resin | a | 100 | 50 | 30 | 20 | 10 | — | — |
| | b | — | 50 | 70 | 80 | 90 | — | 100 |
| | c | — | — | — | — | — | 100 | — |

| | | | | | | | |
|---|---|---|---|---|---|---|---|
| Antifoaming agent | 0.02 | 0.02 | 0.02 | 0.02 | 0.02 | 0.02 | 0.02 |
| Acid anhydride system curing agent | 80 | 100 | 110 | 115 | 120 | 90 | 130 |
| Deterioration preventing agent | 1 | 1 | 1 | 1 | 1 | 1 | 1 |
| Modifying agent | 2 | 2 | 2 | 2 | 2 | 2 | 2 |
| Curing accelerator | 1 | 1 | 1 | 1 | 1 | 1 | 1 |

Using each of the epoxy resin compositions obtained in this manner, its glass transition temperature, cracking resistance, heat resistance, hygroscopic property and bending strength were measured and evaluated in accordance with the following respective methods. On the other hand, using each of the thus obtained epoxy resin compositions, an optical semiconductor device was prepared and its wire break proportion defective was measured and its appearance was also evaluated in accordance with the following respective methods. These results are shown in the following Table 2.

Glass Transition Temperature:

Using each of the epoxy resin compositions, a hardened product test piece of 20 mm×5 mm×5 mm in thickness was prepared (hardening condition: 120° C.×1 hour+150° C.×3 hours). Using the aforementioned test piece, glass transition temperature was measured at a programming rate of 2° C./minute by a thermal analyzer (TMA, TMA-50 manufactured by Shimadzu Corp.).

Cracking Resistance:

Using each epoxy resin composition, a GaP system LED was sealed by potting (120° C.×1 hour) to a shell type lamp of 5 mm in diameter, and an optical semiconductor device was prepared by further hardening at 150° C. for 3 hours. Under a thermal cycle condition of 1 cycle being −25° C.×30 minutes<-->125° C.×30 minutes, crack generation ratio (% defective) after 500 cycles was measured. In this case, the number of samples (n number) of each optical semiconductor was set to 20.

Heat Resistance:

Using each epoxy resin composition, a test piece of 1 mm in thickness was prepared (hardening condition: 120° C.×1 hour+150° C.×3 hours). Using this test piece, deterioration of light transmittance during storage (initial, after 200 hours of storage, after 500 hours of storage) under an atmosphere of 150° C. was measured. Using a spectrophotometer UV3101 manufactured by Shimadzu Corp., light transmittance at a wavelength of 450 nm was measured at room temperature (25° C.), and its decreasing ratio was calculated.

Hygroscopic Property:

Using each epoxy resin composition, a test piece of 1 mm in thickness was prepared (hardening condition: 120° C.×1 hour+150° C.×3 hours). Using this test piece, coefficient of moisture absorption after 169 hours under 85° C./85% RH was measured.

Bending Strength:

Using each epoxy resin composition, a test piece of 100 mm×10 mm×5 mm in thickness was prepared (hardening condition: 120° C.×1 hour+150° C.×3 hours). Using this test piece, bending rupture strength was measured by an autography (AG-500C, mfd. by Shimadzu Corp.) at a head speed of 5 mm/minutes.

TABLE 2

| | | | | | | | Comparative | | |
|---|---|---|---|---|---|---|---|---|---|
| | | | Examples | | | | Examples | | |
| | | | 1 | 2 | 3 | 4 | 1 | 2 | 3 |
| Glass transition temp. (° C.) | | | 142 | 150 | 158 | 165 | 172 | 133 | 195 |
| Heat | Light | Initial | 98 | 98 | 97 | 98 | 97 | 98 | 97 |
| resistance | transmittance | After 200 | 84 | 82 | 83 | 83 | 83 | 78 | 83 |
| | (%) | hrs | | | | | | | |
| | | After 500 | 62 | 63 | 63 | 62 | 61 | 42 | 60 |
| | | hrs | | | | | | | |

| | | | | | | | |
|---|---|---|---|---|---|---|---|
| Hygroscopic property (% by weight) | 1.8 | 1.9 | 2.0 | 2.0 | 2.2 | 1.5 | 2.5 |
| Cracking resistance (%) | 0 | 0 | 0 | 30 | 60 | 0 | 70 |
| Bending strength (N/mm²) | 105 | 100 | 91 | 88 | 83 | 120 | 78 |

Based on the above results, it is evident that glass transition temperature of the products of Examples was not high, deterioration of transmittance was also inhibited in their heat resistance test, and reduction of coefficient of moisture absorption was achieved. In addition, the ratio of crack generation due to thermal stress was also reduced and the resin strength was improved, too.

On the contrary, the product of Comparative Example 1 showed high glass transition temperature and high coefficient of moisture absorption, because mixing ratio of the alicyclic epoxy resin represented by structural formula (1) was 10% by weight of the whole epoxy resin components. In addition, its crack generation ratio was high thus showing poor reliability, and its resin strength was also low. In the case of the product of Comparative Example 2, a bisphenol A type epoxy resin was used as the epoxy resin, so that its glass transition temperature was not high and its cracking resistance was also excellent, but deterioration of transmittance in the heat resistance test was considerable. Also, in the case of the product of Comparative Example 3, the alicyclic epoxy resin represented by structural formula (2) was used as the epoxy resin, so that its glass transition temperature was high and its coefficient of moisture absorption was also high. In addition, its crack generation ratio was high thus showing poor reliability, and its resin strength was also low.

While the invention has been described in detail and with reference to specific embodiments thereof, it will be apparent to one skilled in the art that various changes and modifications can be made therein without departing from the scope thereof.

This application is based on Japanese patent application No. 2004-148182 filed May 18, 2004, the entire contents thereof being hereby incorporated by reference.

1. An epoxy resin composition for optical semiconductor element encapsulation, which comprises the following components (A) to (C);
(A) an epoxy resin composition comprising the alicyclic epoxy resin represented by the following structural formula (1) in an amount of 20% by weight or more based on the entire epoxy resin components, 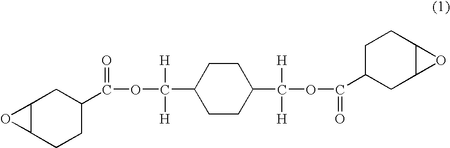
(B) a curing agent, and
(C) a curing accelerator.

2. An optical semiconductor device which comprises an optical semiconductor element and the epoxy resin composition for optical semiconductor element encapsulation of claim 1 which encapsulates the optical semiconductor element.
